(19) United States
(12) Patent Application Publication
(10) Pub. No.: US 2010/0193929 A1
(43) Pub. Date: Aug. 5, 2010

(54) SEMICONDUCTOR DEVICE

(75) Inventors: Ken IWAKURA, Tokyo (JP); Mitsuaki Katagiri, Tokyo (JP); Satoshi Isa, Tokyo (JP); Dai Sasaki, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/686,567

(22) Filed: Jan. 13, 2010

(30) Foreign Application Priority Data
Jan. 30, 2009 (JP) 2009-019931

(51) Int. Cl. H01L 23/522

(52) U.S. Cl. 257/686; 257/700; 257/E23.142; 257/E23.023

(57) ABSTRACT

A semiconductor device includes a package board, first connectors, and a first multi-layered structure. The package board has first and second regions. The first connectors are in the first region. The first multi-layered structure includes a first semiconductor chip, a wiring board, and second to fifth connectors. The first semiconductor chip has first and second surfaces. The first surface covers the second region. The wiring board has third and fourth surfaces. The third surface is fixed to the second surface. The second to fourth connectors are in the center regions of the second to fourth surfaces, respectively. The fifth connectors are aligned along opposing two sides of the fourth surface. The second connectors electrically connect to the third connectors. The third connectors electrically connect to the fourth and fifth connectors. The first connectors electrically connect to the fourth and fifth connectors.

### BACKGROUND OF THE INVENTION

1. Field of the Invention

The present invention relates to a semiconductor device including a multi-layered structure mounted on a package board, the multi-layered structure including a semiconductor chip and a print wiring board fixed to the semiconductor chip through an insulating layer.

Priority is claimed on Japanese Patent Application No. 2009-019931, filed Jan. 30, 2009, the content of which is incorporated herein by reference.

2. Description of the Related Art

Recently, demands for smaller and thinner semiconductor devices have been increasing with the recent high-density packaging. To meet the demands, a semiconductor device having a multi-layered structure in which multiple semiconductor chips are stacked on a package board has been proposed.

As an example of a general multi-layered structure of semiconductor chips, FIG. 11 illustrates a structure including a semiconductor chip 101a on a package board (print wiring board) 100 and another semiconductor chip 101b fixed to the semiconductor chip 101a through a spacer 102. In this case, electrode pads 103a and 103b are aligned along opposing sides of the semiconductor chips 101a and 101b, respectively. For this reason, the electrode pads 103a and 103b can be connected to connection lands 104 provided around the semiconductor chip 101a using relatively short wires 105a and 105b, respectively.

On the other hand, in a case of DRAM (Dynamic Random Access Memory) having a structure in which electrode pads are aligned in the center region of a semiconductor chip, the electrode pads on the semiconductor chip have to be connected to connection lands on a package board using relatively long wires. For this reason, the spacer 102 cannot be provided between the upper and lower semiconductor chips 101a and 101b.

Japanese Patent Laid-Open Publication No. 2004-312008 discloses such a multi-layered structure of semiconductor chips in which electrode pads are aligned in the center region of the semiconductor chip. Specifically, as shown in FIG. 12A, the semiconductor chip 202a is on a package board 200. Another semiconductor chip 202b is fixed to the semiconductor chip 202a through an insulating layer 201. Signal and power electrode pads 203 in the center regions of the semiconductor chips 202a and 202b are connected to connection lands 204 on the package board 200 using long wires 205.

Japanese Patent Laid-Open Publication No. 2001-085609 discloses a similar structure. Specifically, as shown in FIG. 12B, a semiconductor chip 301a is on a package board 300. Another semiconductor chip 301b is fixed on the semiconductor chip 301a. Electrode pads 302a in the center region of a bottom surface of the semiconductor chip 301a are connected to connection lands 304a on a bottom surface of the package board 300 using short wires 305a passing through an opening of the package board 300. Electrode pads 302b in the center region of a top surface of the semiconductor chip 301b are connected to connection lands 304b on a top surface of the package board 300 using long wires 305b.

In this case, a circuit is formed on the bottom surface of the package board 300 using wires thicker than the wires 305a and 305b. However, the signal and power electrode pads 302b on the top surface of the semiconductor chip 301b are connected to the connection lands 304b using the long wires 305b, thereby causing the larger impedance, noises, or a voltage drop, and preventing high-speed operation.

Japanese Patent Laid-Open Publication No. 2006-165303 discloses a multi-layered structure for reducing the power impedance. Specifically, as shown in FIG. 13, a multi-layered structure 403A is on a package board 404. Another multi-layered structure 403B is fixed to the multi-layered structure 403A through an insulating layer 405. Each of the multi-layered structures 403A and 403B includes a semiconductor chip 400 and a print wiring board 402 fixed to the semiconductor chip 400 through an insulating layer 401.

Electrode pads 406 on a top surface of each semiconductor chip 400 are connected by flip-chip connection to connection lands 407 on a lower surface of the corresponding print wiring board 402. Connection lands 409 aligned along opposing sides of each print wiring board 402 are connected by wire-bonding to connection lands 410 on the package board 400 using wires 411.

In this case, signal and power wirings on the bottom surface of the print wiring board 402 are extended from the center region to the peripheral region of the print wiring board 402. Consequently, the power impedance can be further reduced than when the electrode pads 203 and 302b on the semiconductor chips 202a, 202b, and 301b shown in FIGS. 12A and 12B are connected to the connection lands 204 and 304b on the package board 200 and 300 using the long wires 205 and 305b.

Regarding the signal impedance, however, wires are present close to the circuit on the top surface of the semiconductor chip 400, thereby causing larger capacity, and therefore causing an operational problem with respect to signal wirings.

Japanese Patent Laid-Open Publication No. 2004-071997 discloses a multi-chip package in which a silicon board having a metal film on a top surface thereof is provided between two stacked semiconductor chips so that a potential is applied to a bottom surface of the upper semiconductor chip through the metal film.

For the above reasons, a multi-layered structure of semiconductor chips achieving faster operation by reducing resistance and inductance for a power wiring circuit requiring a reduction in impedance and by reducing capacity for a signal wiring circuit requiring a reduction in capacity is required.

### SUMMARY

In one embodiment, a semiconductor device includes a package board, first connectors, and a first multi-layered structure. The package board has first and second regions. The first connectors are in the first region. The first multi-layered structure includes a first semiconductor chip, a wiring board, and second to fifth connectors. The first semiconductor chip has first and second surfaces. The first surface covers the second region. The wiring board has third and fourth surfaces. The third surface is fixed to the second surface. The second to fourth connectors are in the center regions of the second to fourth surfaces, respectively. The fifth connectors are aligned along two opposing sides of the fourth surface. The second connectors electrically connect to the third connectors. The third connectors electrically connect to the fourth and fifth connectors. The first connectors electrically connect to the fourth and fifth connectors.

Accordingly, the semiconductor device can reduce the capacity for a signal wiring circuit requiring a reduction in capacity, and reduce the resistance and the inductance for a power wiring circuit requiring a reduction in impedance, thereby preventing noises and a voltage drop, and therefore achieving faster operation.

### BRIEF DESCRIPTION OF THE DRAWINGS

The above features and advantages of the present invention will be more apparent from the following description of certain preferred embodiments taken in conjunction with the accompanying drawings, in which:

FIGS. 1 and 2 are cross-sectional and plane views illustrating a semiconductor device according to a first embodiment of the present invention, respectively;

FIG. 3 is a plane view illustrating a print wiring board;

FIG. 4 is a cross-sectional view illustrating a main part of a multi-layered structure;

FIG. 5 is an oblique view illustrating the semiconductor device according to the first embodiment;

FIG. 6 is a cross-sectional view illustrating a semiconductor device according to a second embodiment of the present invention;

FIG. 7 is a cross-sectional view illustrating a semiconductor device according to a third embodiment of the present invention;

FIG. 8 is a cross-sectional view illustrating a semiconductor device according to a fourth embodiment of the present invention;

FIG. 9 is a cross-sectional view illustrating a semiconductor device according to a fifth embodiment of the present invention;

FIG. 10 is a cross-sectional view illustrating a semiconductor device according to a sixth embodiment of the present invention; and

FIGS. 11, 12A, 12B, and 13 are cross-sectional views illustrating conventional multi-chip structures.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

Hereinafter, a semiconductor device 1 according to a first embodiment of the present invention is explained. FIG. 1 is a cross-sectional view illustrating the semiconductor device 1. The cross-sectional view is taken so that a signal wiring circuit and a power wiring circuit of a multi-layered structure 3 that will be explained later are included therein.

The semiconductor device 1 includes: a package board 2; a multi-layered structure 3 on the package board 2; a seal 4 made of mold resin covering the multi-layered structure 3 and an upper surface of the package board 2; and solder balls 5 on a bottom surface of the package board 2. Thus, the semiconductor device 1 has a BGA (Ball Grid Array) structure.

The package board 2 is made of a print wiring board that is rectangular in plane view (i.e., when viewed in a direction perpendicular to the top and bottom surfaces thereof). The top surface of the package substrate 2 has a mounting region 2a in which the multi-layered structure 3 is mounted. Multiple signal and power connection lands 6a and 6b are aligned along the mounting region 2a.

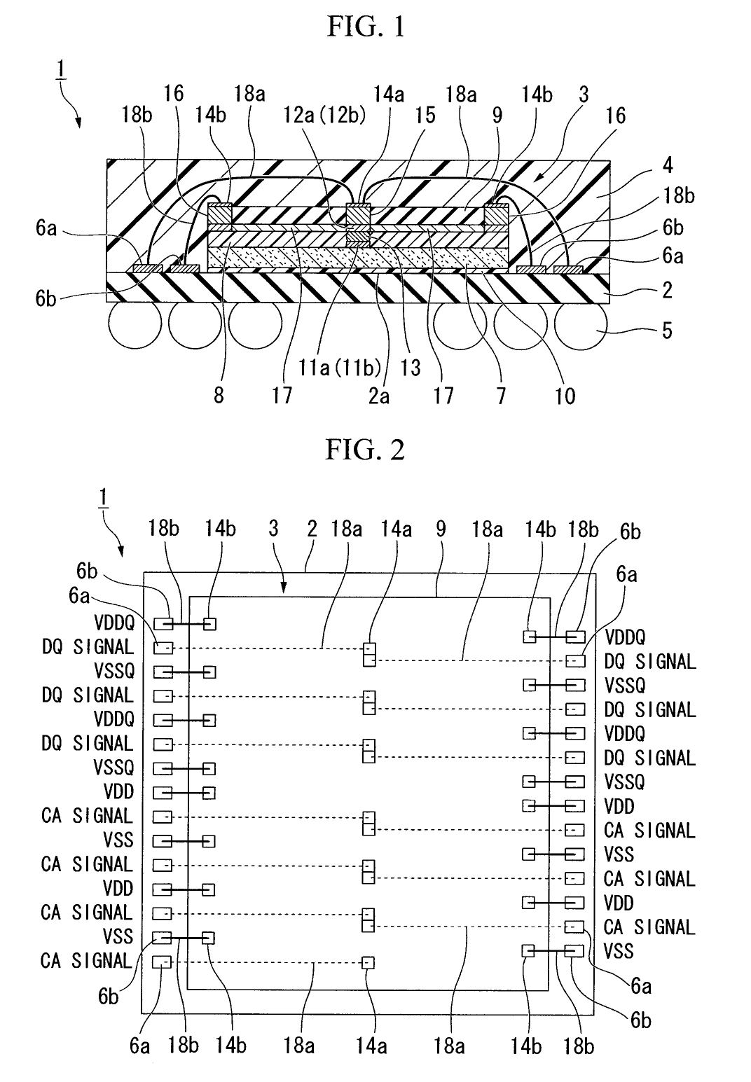

The connection lands 6a and 6b are aligned in straight lines along two opposing sides of the multi-layered structure 3 as shown in FIG. 2. Since the signal connection lands 6a and the power (VDD, VDDQ, VSS, VSSQ) connection pads 6b that are aligned in a straight line cannot be simultaneously illustrated in FIG. 1, the signal connection lands 6a are illustrated outside the power connection lands 6b for convenience.

Although not shown, vias, a wiring pattern, and the like for electrically connecting the connection lands 6a and 6b to the corresponding solder balls 5 are provided in the package board 2.

The multi-layered structure 3 includes: a semiconductor chip 7 fixed to the mounting region 2a of the package board 2 through an insulating adhesive 10; and a print wiring board 9 fixed to the semiconductor chip 7 through an insulating resin layer 8.

The semiconductor chip 7 is rectangular in the plane view. The semiconductor chip 7, the print wiring board 9, and the insulating resin layer 8 have substantially the same size in the plane view. The semiconductor chip 7 is connected by a flip-chip connection to the print wiring board 9, thereby reducing the size of the multi-layered structure 3 in the height direction.

Specifically, multiple signal electrode pads 11a and multiple power electrode pads 11b are aligned in a straight line in the center region of the top surface of the semiconductor chip 7. Since the signal electrode pads 11a and the power (VDD, VDDQ, VSS, VSSQ) electrode pads 11b that are aligned in a straight line cannot be simultaneously illustrated in FIG. 1, the signal-and-power electrode pads 11a and 11b are collectively illustrated for convenience.

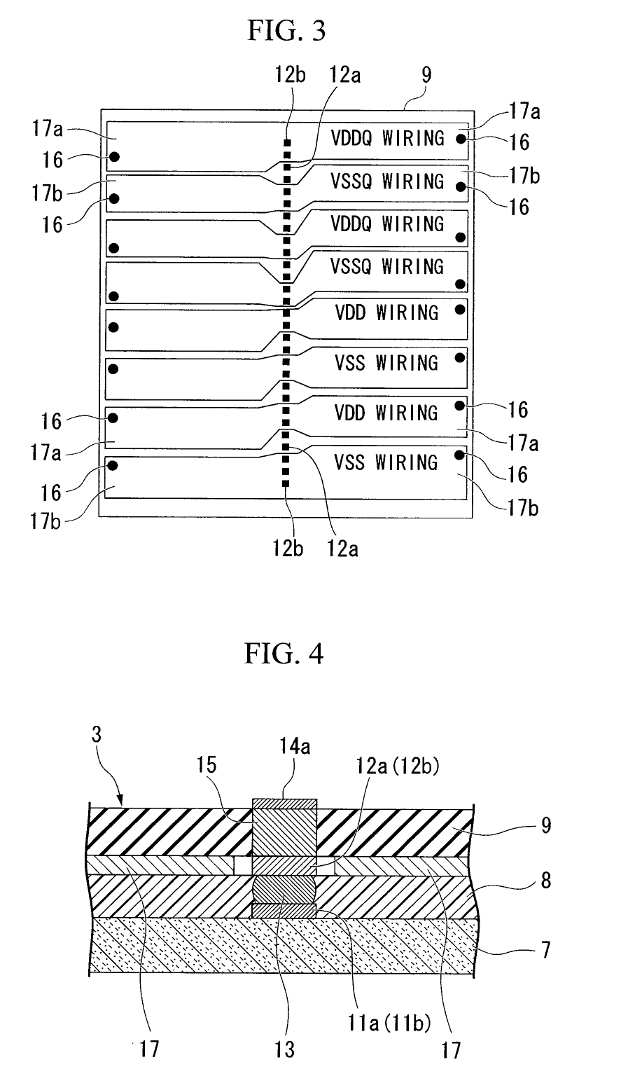

Multiple signal connection lands 12a and multiple power connection lands 12b are aligned in a straight line in the center region of the bottom surface of the print wiring board 9 so as to face the electrode pads 11a and 11b on the top surface of the semiconductor chip 7, respectively, as shown in FIGS. 1 and 3. Since the signal electrode pads 12a and the power (VDD, VDDQ, VSS, VSSQ) electrode pads 12b that are aligned in a straight line cannot be simultaneously illustrated in FIG. 1, the signal-and-power electrode pads 12a and 12b are collectively illustrated for convenience.

As shown in FIG. 4 enlarging the multi-layered structure 3, the electrode pads 11a and 11b on the top surface of the semiconductor chip 7 are electrically connected by face-down bonding to the electrode pads 12a and 12b on the bottom surface of the print wiring board 9 through bumps 13. Additionally, the insulating layer 8 seals space between the semiconductor chip 7 and the print wiring board 9 (this structure is called a “flip-chip structure”). Accordingly, space for drawing wires is unnecessary compared with the case of wire-bonding connection, thereby reducing the size in the height direction.

As shown in FIGS. 1 and 3, signal connection lands 14a and power connection lands 14b are aligned on a top surface of the print wiring board 9. The signal connection lands 14a are aligned in a straight line in the center region of the top surface of the print wiring board 9 so as to face the signal connection lands 12a on the bottom surface of the print wiring board 9.

The power connection lands 14b are aligned in straight lines along two opposing sides of the print wiring board 9. Since the signal-and-power connection lands 14a and 14b cannot be simultaneously illustrated in FIG. 1, those connection lands 14a and 14b are illustrated in the same cross-section for convenience.

The signal connection pads 14a on the top surface of the print wiring board 9 are electrically connected to the signal connection lands 12a on the bottom surface of the print wiring board 9 through conductors 15 called vias penetrating the print wiring board 9 (this structure is called a “pad-on-via structure”). Thus, the signal wiring circuit is formed.

The power connection lands 14b are aligned in straight lines along two opposing sides of the print wiring board 9. The power connection lands 14b are electrically connected (inter-layer connection) to a wiring portion 17 on the bottom surface of the print wiring board 9 through conductors 16 called vias penetrating the print wiring board 9.

Specifically, as shown in FIG. 3, the wiring portion 17 on the bottom surface of the print wiring board 9 includes conductive patterns 17a corresponding to the power wirings (VDD and VDDQ) and conductive patterns 17b corresponding to the ground wiring (VSS and VSSQ). Each of the conductive patterns 17a and 17b electrically connects the conductors 16 on both sides of the print wiring board 9 to the power connection lands 12b. The signal connection lands 12a are electrically insulated from the conductive patterns 17a and 17b.

The power connection lands 14b on the top surface of the print wiring board 7 are electrically connected to the power connection lands 12b on the bottom surface of the print wiring board 9 through the conductors 16 and the wiring portion 17. Thus, the power wiring circuit is formed.

As shown in FIGS. 1, 2, and 5, the multi-layered structure 3 is connected by wire bonding to the package board 2. Specifically, regarding the signal wiring circuit, the signal connection lands 14a in the center region of the print wiring board 9 are electrically connected (wire-bonding connection) to the signal connection lands 6a aligned along two opposing sides of the package board 2 using relatively long wires 18a.

On the other hand, regarding the power wiring circuit, the power connection lands 14b aligned along the two opposing sides of the print wiring board 9 are electrically connected (wire-bonding connection) to the power connection lands 6b aligned along the two opposing sides of the package board 2 using relatively short wires 18b.

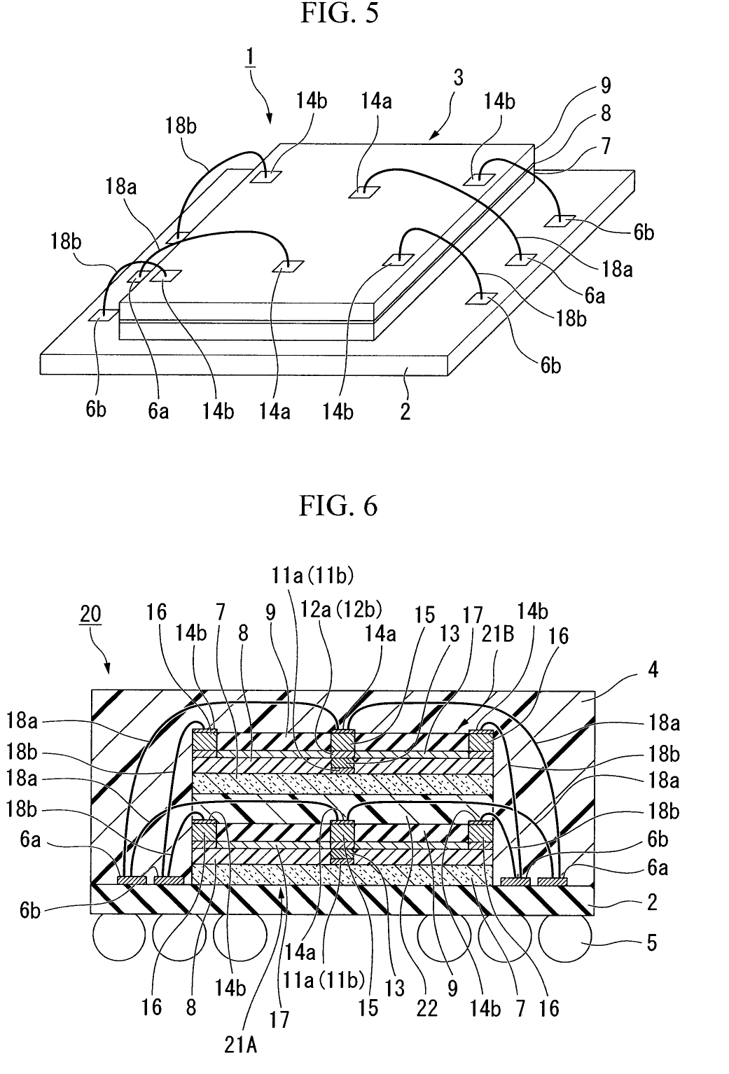

Although it is illustrated in FIG. 1 for convenience that the two wires 18a extending from the opposing sides of the package board 2 connect to the same signal connection land 14a, the two wires 18a actually connect to the different connection lands 14a aligned in a straight line as shown in FIGS. 2 and 5.

In FIG. 2, dashed and solid lines denote the signal and power wires 18a and 18b, respectively. In FIG. 5, illustrations of the signal connection pads 6a and 14a, the signal wires 18a, the power connection pads 6b and 14b, and the power wires 18b are simplified.

According to the semiconductor device 1, regarding the signal wiring circuit of the multi-layered structure 3, the connection lands 14a in the center region of the print wiring board 9 are connected to the connection lands 6a on the package board 2 using the relatively long wires 18a, thereby enabling a reduction in capacity.

On the other hand, regarding the power wiring circuit of the multi-layered structure 3, the connection lands 14b aligned along the two opposing sides of the print wiring board 9 are connected to the connection lands 6b on the package board 2 using the relatively short wires 18b while the wiring portion 17 (conductive patterns 17a and 17b) on the bottom surface of the print wiring board 9 has a large width, thereby enabling a reduction in the resistance and in the inductance.

Accordingly, the semiconductor device 1 can reduce the capacity for the signal wiring circuit requiring a reduction in capacity, and reduce the resistance and the inductance for the power wiring circuit requiring a reduction in the impedance, thereby preventing noises and a voltage drop, and therefore achieving faster operation.

### Second Embodiment

Hereinafter, a semiconductor device 20 according to a second embodiment of the present invention is explained with reference to FIG. 6. The semiconductor device 20 includes a multi-layered structure 21A on the package board 2 and a multi-layered structure 21B fixed to the multi-layered structure 21A through an insulating resin layer 22.

Each of the multi-layered structures 21A and 21B has the same structure as that of the multi-layered structure 3. Other elements have substantially the same structures as those of the semiconductor device 1.

For this reason, explanations of the same elements as those of the semiconductor device 1 are omitted hereinafter, and like reference numerals denote like elements between the first and second embodiments.

Similar to the semiconductor device 1, according to the semiconductor device 20, regarding the signal wiring circuit of the multi-layered structures 21A and 21B, the connection lands 14a in the center region of the print wiring board 9 are connected to the connection lands 6a on the package board 2 using the relatively long wires 18a, thereby enabling a reduction in capacity.

On the other hand, regarding the power wiring circuit of the multi-layered structures 21A and 21B, the connection lands 14b aligned along the two opposing sides of the print wiring board 9 are connected to the connection lands 6b on the package board 2 using the relatively short wire 18b while the wiring portion 17 (conductive patterns 17a and 17b) on the bottom surface of the print wiring board 9 has a large width, thereby enabling a reduction in the resistance and in the inductance.

Accordingly, the semiconductor device 20 can reduce the capacity for the signal wiring circuit requiring a reduction in capacity, and reduce the resistance and the inductance for the power wiring circuit requiring a reduction in the impedance, thereby preventing noises and a voltage drop, and therefore achieving faster operation.

### Third Embodiment

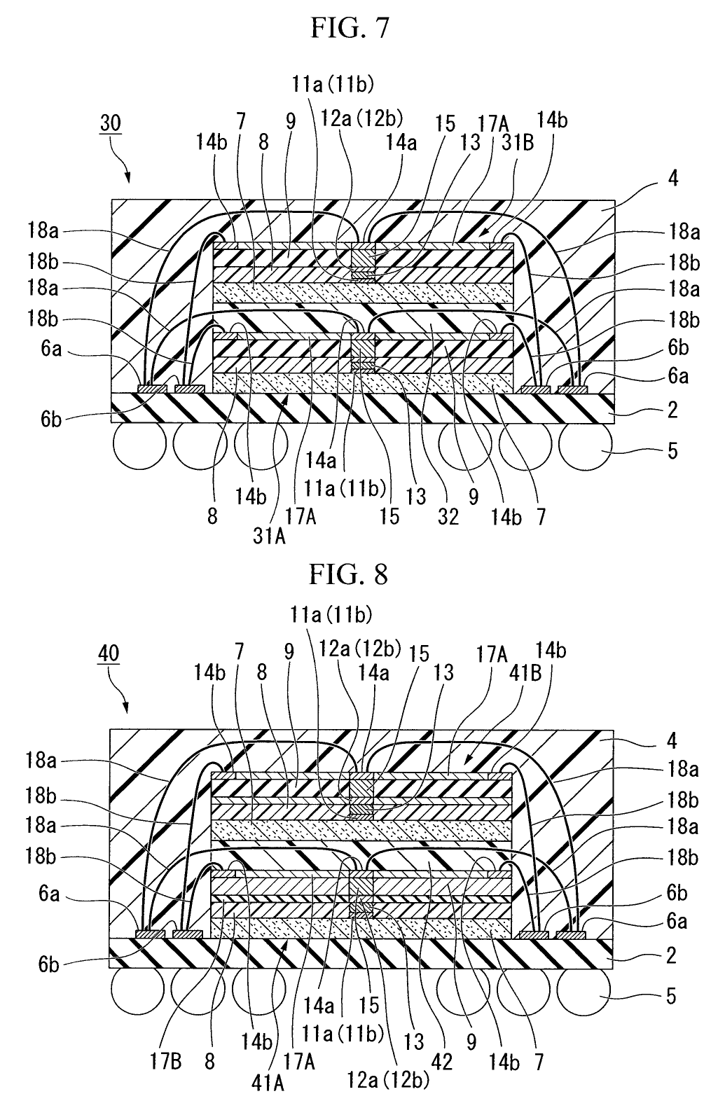

Hereinafter, a semiconductor device 30 according to a third embodiment of the present invention is explained with reference to FIG. 7. The semiconductor device 30 includes a multi-layered structure 31A on the package board 2 and a multi-layered structure 31B fixed to the multi-layered structure 31A through an insulating resin layer 32.

The semiconductor device 30 has substantially the same structure as those of the semiconductor devices 1 and 20 except that the wiring portion 17A is provided on the top surface of the print wiring board 9 while the wiring portion 17 of the semiconductor devices 1 and 20 is provided on the bottom surface of the print wiring board 9.

For this reason, explanations of the same elements as those of the semiconductor devices 1 and 20 are omitted hereinafter, and like reference numerals denote like elements among the first to third embodiments.

Although not shown, the wiring portion 17A on the top surface of the print wiring board 9 includes conductive patterns corresponding to the power wirings (VDD and VDDQ) and conductive patterns corresponding to the ground wirings (VSS and VSSQ).

The power connection lands 14b aligned along two opposing sides of the print wiring board 9 are electrically connected (inter-layer connection) to the power connection lands 12b through conductors called vias penetrating the print wiring board 9. On the other hand, the signal connection pads 14a are electrically connected (inter-layer connection) to the signal connection lands 12a through conductors called vias penetrating the print wiring board 9.

Similar to the semiconductor devices 1 and 20, according to the semiconductor device 30, regarding the signal wiring circuits of the multi-layered structures 31A and 31B, the connection lands 14a in the center region of the print wiring board 9 are connected to the connection lands 6a on the package board 2 using the relatively long wires 18a, thereby enabling a reduction in capacity.

On the other hand, regarding the power wiring circuits of the multi-layered structures 31A and 31B, the connection lands 14b aligned along the two opposing sides of the print wiring board 9 are connected to the connection lands 6b on the package board 2 using the relatively short wire 18b while the wiring portion 17A on the top surface of the print wiring board 9 has a large width, thereby enabling a reduction in the resistance and in the inductance.

Accordingly, the semiconductor device 30 can reduce the capacity for the signal wiring circuit requiring a reduction in capacity, and reduce the resistance and the inductance for the power wiring circuit requiring a reduction in the impedance, thereby preventing noises and a voltage drop, and therefore achieving faster operation.

### Fourth Embodiment

Hereinafter, a semiconductor device 40 according to a fourth embodiment of the present invention is explained with reference to shown in FIG. 8. The semiconductor device 40 includes a multi-layered structure 41A on the package board 2 and a multi-layered structure 41B fixed to the multi-layered structure 41A through an insulating resin layer 42.

The semiconductor device 40 has substantially the same structures as those of the semiconductor devices 1, 20, and 30 except that wiring portions 17A and 17B are provided on both top and bottom surfaces of the print wiring board 9, respectively. For this reason, explanations of the same elements as those of the semiconductor devices 1, 20, and 30 are omitted hereinafter, and like reference numerals denote like elements among the first to fourth embodiments.

Similar to the semiconductor devices 1, 20, and 30, according to the semiconductor device 40, regarding the signal wiring circuits of the multi-layered structures 41A and 41B, the connection lands 14a in the center region of the print wiring board 9 are connected to the connection lands 6a on the package board 2 using the relatively long wires 18a, thereby enabling a reduction in capacity.

On the other hand, regarding the power wiring circuits of the multi-layered structures 41A and 41B, the connection lands 14b aligned along the two opposing sides of the print wiring board 9 are connected to the connection lands 6b on the package board 2 using the relatively short wire 18b while the wiring portions 17A and 17B on the top and bottom surfaces of the print wiring board 9 have a large width, thereby enabling a reduction in the resistance and in the inductance.

Accordingly, the semiconductor device 40 can reduce the capacity for the signal wiring circuit requiring a reduction in capacity, and reduce the resistance and the inductance for the power wiring circuit requiring a reduction in the impedance, thereby preventing noises and a voltage drop, and therefore achieving faster operation.

### Fifth Embodiment

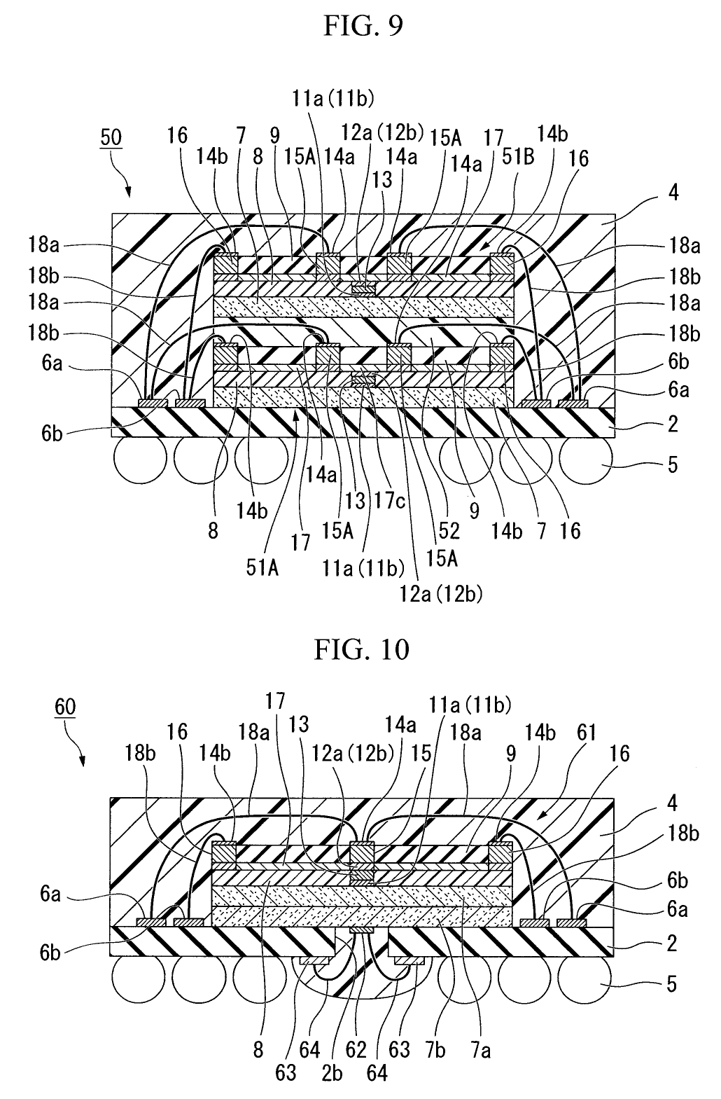

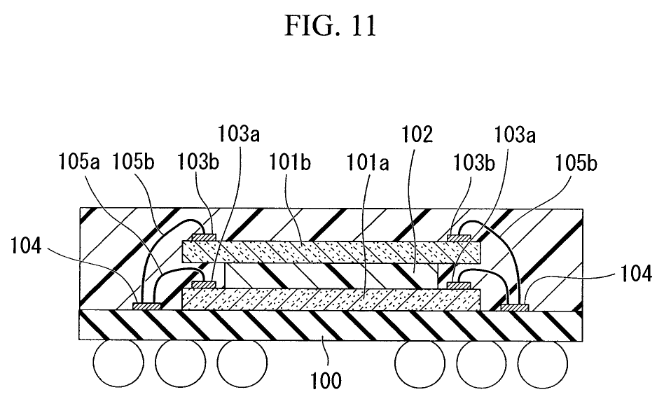

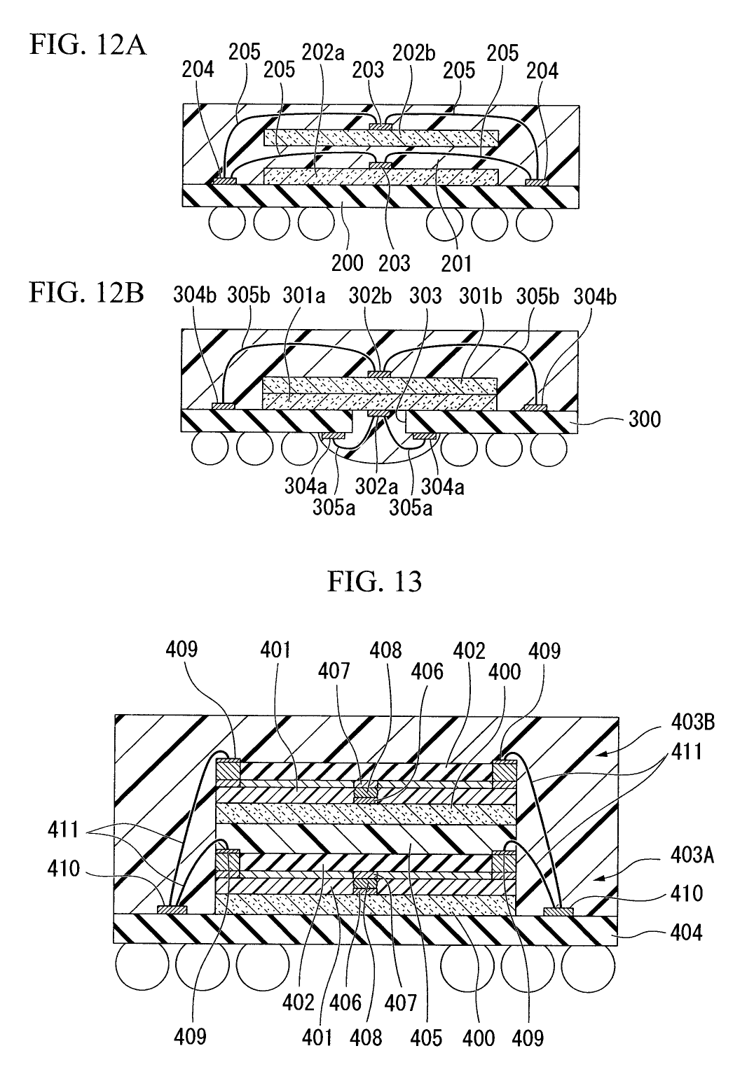

Hereinafter, a semiconductor device 50 according to a fifth embodiment of the present invention is explained with reference to FIG. 9. The semiconductor device 50 includes a multi-layered structure 51A on the package board 2 and a multi-layered structure 51B fixed to the multi-layered structure 51A through an insulating resin layer 52.

The semiconductor device 50 has substantially the same structures as those of the semiconductor devices 1 and 20 except for the following. Each of the multi-layered structures 51A and 51B includes the signal connection lands 14a aligned in two straight lines in the center region of the top surface of the print wiring board 9.

Additionally the two lines of the signal connection lands 14a are electrically connected to a wiring portion 17C on the bottom surface of the print wiring board 9 through conductors 15A. Further, the two lines of the signal connection lands 14a are electrically connected to the signal connection lands 12a through the wiring portion 17C.

For this reason, explanations of the same elements as those of the semiconductor devices 1 and 20 are omitted hereinafter, and like reference numerals denote like elements among the first, second, and fifth embodiments.

Similar to the semiconductor devices 1 and 20, according to the semiconductor device 50, regarding the signal wiring circuits of the multi-layered structures 51A and 51B, the connection lands 14a in the center region of the print wiring board 9 are connected to the connection lands 6a on the package board 2 using the relatively long wires 18a, thereby enabling a reduction in capacity.

On the other hand, regarding the power wiring circuits of the multi-layered structures 51A and 51B, the connection lands 14b aligned along the two opposing sides of the print wiring board 9 are connected to the connection lands 6b on the package board 2 using the relatively short wire 18b while the wiring portion 17 (conductive patterns 17a and 17b) on the bottom surface of the print wiring board 9 has a large width, thereby enabling a reduction in the resistance and in the inductance.

Accordingly, the semiconductor device 50 can reduce the capacity for the signal wiring circuit requiring a reduction in capacity, and reduce the resistance and the inductance for the power wiring circuit requiring a reduction in the impedance, thereby preventing noises and a voltage drop, and therefore achieving faster operation.

### Sixth Embodiment

Hereinafter, a semiconductor device 60 according to a sixth embodiment of the present invention is explained with reference to FIG. 10. The semiconductor device 60 includes a multi-layered structure 61 on the package board 2. The multi-layered structure 61 includes two semiconductor chips 7a and 7b that are stacked, and the print wiring board 9 fixed to the upper semiconductor chip 7a through the insulating resin layer 8.

Additionally, signal-and-power connection pads 62 are provided on a bottom surface of the lower semiconductor chip 7b, while connecting to signal-and-power connection pads 63 on the bottom surface of the package board 2 through wires 64 passing through an opening in the package board 2. Other elements have the same structure as those of the semiconductor device 1.

For this reason, explanations of the same elements as those of the semiconductor device 1 are omitted hereinafter, and like reference numerals denote like elements among the first and sixth embodiments.

Similar to the semiconductor device 1, according to the semiconductor device 60, regarding the signal wiring circuit of the multi-layered structure 61, the connection lands 14a in the center region of the print wiring board 9 are connected to the connection lands 6a on the package board 2 using the relatively long wires 18a, thereby enabling a reduction in capacity.

On the other hand, regarding the power wiring circuit of the multi-layered structure 61, the connection lands 14b aligned along the two opposing sides of the print wiring board 9 are connected to the connection lands 6b on the package board 2 using the relatively short wire 18b while the wiring portion 17 (conductive patterns 17a and 17b) on the bottom surfaces of the print wiring board 9 has a large width, thereby enabling a reduction in the resistance and in the inductance.

Accordingly, the semiconductor device 60 can reduce the capacity for the signal wiring circuit requiring a reduction in capacity, and reduce the resistance and the inductance for the power wiring circuit requiring a reduction in the impedance, thereby preventing noises and a voltage drop, and therefore achieving faster operation.

It is apparent that the present invention is not limited to the above embodiments, but may be modified and changed without departing from the scope and spirit of the invention.

For example, the number of multi-layered structures stacked on the package board 2, and the number of semiconductor chips stacked in each of the multi-layered structures can be appropriately modified.

The present invention is applicable to a semiconductor device, such as DRAM, which includes a multi-layered structure mounted on a package board, the multi-layered structure including a semiconductor chip and a print wiring board fixed to the semiconductor chip through an insulating layer.

Additionally, the present invention is applicable to various semiconductor devices, such as a data processor or ROM (Read Only Memory).

What is claimed is:

1. A semiconductor device comprising:
a package board having first and second regions;
a plurality of first connectors in the first region; and
a first multi-layered structure comprising:
a first semiconductor chip having first and second surfaces, the first surface covering the second region;
a wiring board having third and fourth surfaces, the third surface being fixed to the second surface;
a plurality of second connectors in the center region of the second surface,
a plurality of third connectors in the center region of the third surface; and
a plurality of fourth connectors in the center region of the fourth surface; and
a plurality of fifth connectors aligned along two opposing sides of the fourth surface;
wherein the plurality of second connectors electrically connect to the plurality of third connectors,
the plurality of third connectors electrically connect to the plurality of fourth and fifth connectors, and
the plurality of first connectors electrically connect to the plurality of fourth and fifth connectors.

2. The semiconductor device according to claim 1, wherein
the first multi-layered structure further comprises:
a first insulating layer connecting the second and third surfaces.

3. The semiconductor device according to claim 1, wherein
the first multi-layered structure further comprises:
a plurality of bumps electrically connecting the plurality of second connectors to the plurality of third connectors.

4. The semiconductor device according to claim 1, wherein
the first multi-layered structure further comprises:
a plurality of first conductors electrically connecting the plurality of third connectors to the plurality of fourth connectors, the plurality of first conductors facing the plurality of third and fourth connectors, and the plurality of first conductors each penetrating the wiring board.

5. The semiconductor device according to claim 1, wherein
the first multi-layered structure further comprises:
a plurality of second conductors facing the plurality of fifth conductors, the plurality of second conductors each penetrating the wiring board; and
a plurality of wiring portions on the third surface, the plurality of wiring portions electrically connecting the plurality of second conductors to the plurality of third connectors.

6. The semiconductor device according to claim 1, wherein
the first multi-layered structure further comprises:
a plurality of wiring portions on the fourth surface, the plurality of wiring portions electrically connecting the plurality of fourth connectors to the plurality of fifth connectors.

7. The semiconductor device according to claim 1, wherein
the first multi-layered structure further comprises:
a plurality of wiring portions on the third and fourth surfaces, the plurality of wiring portions on the fourth surface electrically connecting the plurality of fourth connectors to the plurality of fifth connectors.

8. The semiconductor device according to claim 1, wherein the plurality of fourth connectors are aligned in two lines.

9. The semiconductor device according to claim 1, further comprising:
a seal covering the first region and the first multi-layered structure.

10. The semiconductor device according to claim 1, further comprising:
a second multi-layered structure fixed to the first multi-layered structure, the first and second multi-layered structures having the same structure.

11. The semiconductor device according to claim 10, further comprising:
a second insulating layer connecting the first and second multi-layered structures.

12. The semiconductor device according to claim 10, further comprising:
a seal covering the first region and the first and second multi-layered structures.

13. The semiconductor device according to claim 1, further comprising:
a plurality of sixth connectors on the package board, the plurality of sixth connectors being on an opposite side of the plurality of the first connectors with respect to the package board,
wherein the package board has a through hole,
the first multi-layered structure further comprises:
a second semiconductor chip fixed to the first surface, the second semiconductor chip covering the second region; and
a plurality of seventh connectors on the second semiconductor chip, the plurality of seventh connectors facing the through hole, the plurality of seventh connectors electrically connecting to the plurality of sixth connectors.

14. The semiconductor device according to claim 13, wherein the plurality of seventh connectors electrically connect to the plurality of sixth connectors through a plurality of wires passing through the through hole.

15. The semiconductor device according to claim 13, further comprising:
a first seal covering the first region and the first multi-layered structure; and
a second seal covering the plurality of sixth and seventh connectors and the through hole.

16. The semiconductor device according to claim 1, wherein the plurality of first connectors comprises a plurality of signal connectors and a plurality of power connectors, the plurality of signal connectors electrically connect to the plurality of fourth connectors, and the plurality of power connectors electrically connect to the plurality of fifth connectors.

17. The semiconductor device according to claim 16, wherein
the plurality of signal connectors electrically connect to the plurality of fourth connectors using a plurality of long wires, and
the plurality of power connectors electrically connect to the plurality of fifth connectors using a plurality of short wires.

18. The semiconductor device according to claim 1, further comprising:
a plurality of solder balls on the package board, the plurality of solder balls being on an opposite side of the plurality of first connectors with respect to the package board.
